(19) United States
(12) Patent Application Publication
(10) Pub. No.: US 2015/0061030 A1
(43) Pub. Date: Mar. 5, 2015

(54) SEMICONDUCTOR STRUCTURE INCLUDING METAL SILICIDE BUFFER LAYERS AND METHODS OF FABRICATING THE SAME

(71) Applicant: Samsung Electronics Co., Ltd., Gyeonggi-do (KR)

(72) Inventors: Mohammad Rakib Uddin, Hwaseong-si (KR); Moon-seung Yang, Hwaseong-si (KR); Dong-soo Lee, Gunpo-si (KR); Myoung-jae Lee, Hwaseong-si (KR); Seong-ho Cho, Gwacheon-si (KR); Eui-chul Hwang, Seongnam-si (KR)

(21) Appl. No.: 14/471,900

(22) Filed: Aug. 28, 2014

(30) Foreign Application Priority Data
Aug. 29, 2013 (KR) 10-2013-0103429

(51) Int. Cl. H01L 29/04; H01L 27/092; H01L 29/16; H01L 29/06; H01L 29/20

(52) U.S. Cl. CPC H01L 29/04; H01L 29/0642; H01L 29/20; H01L 29/16; H01L 27/092
USPC 257/369

(57) ABSTRACT

Provided are semiconductor structures and methods of fabricating the same. The semiconductor structure includes a silicon substrate, at least one semiconductor layer that is grown on the silicon substrate and has a lattice constant in a range from about 1.03 to about 1.09 times greater than that of the silicon substrate, and a buffer layer that is disposed between the silicon substrate and the semiconductor layer and includes a metal silicide compound for lattice matching with the semiconductor layer. Related fabrication methods are also discussed.

### CROSS-REFERENCE TO RELATED APPLICATIONS

This application claims priority from Korean Patent Application No. 10-2013-0103429, filed on Aug. 29, 2013, in the Korean Intellectual Property Office, the disclosure of which is incorporated herein in its entirety by reference.

### BACKGROUND

1. Field

The present disclosure relates to semiconductor structures and methods of fabricating the same, and more particularly, to semiconductor structures in which a semiconductor is epitaxially grown on a silicon substrate and methods of fabricating the same.

2. Description of the Related Art

Research into developing devices that use compound semiconductors have been conducted. In particular, research into replacing a silicon semiconductor material with a group III-V material, for example, gallium arsenide GaAs, and/or a group IV material, for example, germanium (Ge), have been conducted.

Research into forming high performance complementary metal-oxide semiconductor (CMOS) have been conducted by using a group III-V material having an electron mobility that is higher than silicon and a semiconductor material having a hole mobility that is higher than silicon.

If GaAs or Ge can be integrated on a large area of a silicon substrate, it may be possible to use conventional silicon manufacturing processes. Accordingly, manufacturing costs may be reduced. However, defects may occur on or at an interface between GaAs or Ge and silicon due to large lattice constants therebetween.

### SUMMARY

Provided are semiconductor structures that minimize or reduce lattice defects and a thickness thereof when a semiconductor layer that includes gallium arsenic and germanium is epitaxially grown on a silicon substrate, and methods of fabricating the same.

Additional aspects will be set forth in part in the description which follows and, in part, will be apparent from the description, or may be learned by practice of the presented embodiments.

According to some embodiments of the inventive concepts, a semiconductor structure includes a silicon substrate, a metal silicide buffer layer on the silicon substrate, and an epitaxial semiconductor layer on the metal silicide buffer layer opposite the silicon substrate. The metal silicide buffer layer having a lattice constant greater than that of the silicon substrate. The epitaxial semiconductor layer has a lattice constant greater than or equal to that of the buffer layer and within about 9 percent of that of the silicon substrate.

In some embodiments, the lattice constant of the epitaxial semiconductor layer may be 3 percent to 9 percent greater than that of the silicon substrate.

In some embodiments, the semiconductor layer may include germanium (Ge), gallium arsenide (GaAs), aluminum arsenide (AlAs), indium gallium arsenide (InGaAs), indium phosphide (InP), and/or indium aluminum arsenide (InAlAs).

In some embodiments, the semiconductor layer may be formed at a lower temperature than and may have fewer cracks than a gallium nitride (GaN) layer.

In some embodiments, the epitaxial semiconductor layer may be substantially free of threading dislocations.

In some embodiments, the semiconductor structure may further include a seed layer having a thickness of about 5 nanometers (nm) to about 10 nm between the metal silicide buffer layer and the epitaxial semiconductor layer. A lattice constant of the seed layer may match the lattice constant of the epitaxial semiconductor layer.

In some embodiments, the epitaxial semiconductor layer may include different first and second epitaxial semiconductor layers that are laterally separated along a surface of the metal silicide buffer layer, defining a CMOS structure.

In some embodiments, the metal silicide buffer layer may include first and second buffer layers laterally separated on a surface of the silicon substrate by an insulating spacer. The insulating spacer may also laterally separate the first and second epitaxial semiconductor layers.

According to an aspect of the present inventive concepts, a semiconductor structure includes: a silicon substrate; at least one semiconductor layer that is formed on the silicon substrate and has a lattice constant in a range from about 1.03 to about 1.09 times greater than that of the silicon substrate; and a buffer layer that is disposed between the silicon substrate and the semiconductor layer and includes a metal silicide compound for lattice matching with the semiconductor layer.

The semiconductor material of the semiconductor layer may include at least one of Ge, GaAs, AlAs, InGaAs, InP, and InAlAs as a semiconductor material.

At least a portion of the buffer layer may have a lattice constant matching with that of the semiconductor layer.

The buffer layer may have a lattice constant that is the same as or smaller than that of the semiconductor layer and greater than that of the silicon substrate.

The buffer layer may include a metal silicide compound that includes at least one of iron (Fe), nickel (Ni), palladium (Pd), manganese (Mn), molybdenum (Mo), tungsten (W), and cobalt (Co).

The buffer layer may have a thickness in a range from about 1 nm to about 10 nm.

The semiconductor structure may further include a seed layer that is disposed between the buffer layer and the semiconductor layer and includes a semiconductor layer material having a lattice constant matching with that of the semiconductor layer.

The seed layer may be formed at a temperature lower than the temperature for forming the semiconductor layer.

A semiconductor material of the seed layer may include at least one of Ge, GaAs, AlAs, InGaAs, InP, and InAlAs.

The seed layer may have a thickness in a range from about 5 nm to about 10 nm.

The semiconductor layer may include a first semiconductor layer and a second semiconductor layer that are separated from each other on the buffer layer, wherein the first semiconductor layer includes Ge and the second semiconductor layer include at least one of GaAs, AlAs, InGaAs, InP, and InAlAs.

The semiconductor structure may further include a spacer disposed between the first semiconductor layer and the second semiconductor layer.

The spacer may be disposed on the silicon substrate or the buffer layer.

The buffer layer may include a first buffer layer and a second buffer layer, wherein at least portion of the first buffer layer has a lattice constant matching with that of the first semiconductor layer, and at least portion of the second buffer layer has a lattice constant matching with that of the second semiconductor layer.

The spacer may include an insulating material.

According to an aspect of the present inventive concepts, a method of fabricating a semiconductor structure in which at least one semiconductor layer that includes a semiconductor material having a lattice constant in a range from about 1.03 to about 1.09 times greater than that of a silicon substrate is formed on the silicon substrate, the method including forming a buffer layer having a metal silicide compound for lattice matching with the semiconductor layer on the silicon substrate before forming the semiconductor layer.

The semiconductor material of the semiconductor layer may include at least one of Ge, GaAs, AlAs, InGaAs, InP, and InAlAs as a semiconductor material.

At least a portion of the buffer layer may have a lattice constant matching with that of the semiconductor layer.

The buffer layer may have a lattice constant that is the same as or smaller than that of the semiconductor layer and greater than that of the silicon substrate.

The forming of the buffer layer may include forming the buffer layer on the silicon substrate by simultaneously co-depositing Si and at least one of Fe, Ni, Pd, Mn, Mo, W, and Co.

The forming of the buffer layer may include forming the buffer layer on the silicon substrate by performing annealing after depositing at least one of Fe, Ni, Pd, Mn, Mo, W, and Co on the silicon substrate.

The buffer layer may have a thickness in a range from about 1 nm to about 10 nm.

The method may further include forming a seed layer on the buffer layer before forming the semiconductor layer on the buffer layer, wherein the seed layer includes a semiconductor material that has a lattice constant matching with that of the semiconductor layer.

The seed layer may be formed at a temperature lower than the temperature for forming the semiconductor layer.

A semiconductor material of the seed layer may include at least one of Ge, GaAs, AlAs, InGaAs, InP, and InAlAs.

The seed layer may have a thickness in a range from about 5 nm to about 10 nm.

The method may further include forming a spacer on a portion of the silicon substrate or the buffer layer before forming the semiconductor layer.

The semiconductor layer may include a first semiconductor layer and a second semiconductor layer that are separated from each other on the buffer layer, wherein the first semiconductor layer includes Ge and is disposed on a side of the spacer, and the second semiconductor layer includes at least one of GaAs, AlAs, InGaAs, InP, and InAlAs and is disposed on the other side of the spacer, and the spacer may include an insulating material.

According to the present inventive concepts, a buffer layer is disposed between the silicon substrate and the semiconductor layer and the buffer layer includes a metal silicide compound for lattice matching with the semiconductor layer. Thus, defects that can occur due to lattice mismatching of the semiconductor layer may be reduced or prevented.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of a semiconductor structure according to some embodiments of the present inventive concepts;

FIGS. 2A through 2C are schematic cross-sectional views showing methods of fabricating the semiconductor structure of FIG. 1, according to some embodiments of the present inventive concepts;

FIGS. 3A through 3C are schematic cross-sectional views showing methods of fabricating the semiconductor structure of FIG. 1, according to further embodiments of the present inventive concepts;

FIG. 4 is a schematic cross-sectional view of a semiconductor structure according to still further embodiments of the present inventive concepts;

FIG. 5 is a schematic cross-sectional view of a semiconductor structure according to yet further embodiments of the present inventive concepts; and

FIG. 6 is a schematic cross-sectional view of a semiconductor structure according to further embodiments of the present inventive concepts.

### DETAILED DESCRIPTION

Reference will now be made in detail to embodiments, examples of which are illustrated in the accompanying drawings, wherein like reference numerals refer to like elements throughout and the sizes of each of the elements may be exaggerated for clarity and conveniences of explanation.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present inventive concept. The term “and/or” includes any and all combinations of one or more of the associated listed items.

It will also be understood that when an element is referred to as being “on” or “connected to” another element, it can be directly on or connected to the other element, or intervening elements may be present. In contrast, when an element is referred to as being “directly on” or “directly connected to” another element, there are no intervening elements present. It will also be understood that the sizes and relative orientations of the illustrated elements are not shown to scale, and in some instances they have been exaggerated for purposes of explanation.

Embodiments are described herein with reference to cross-sectional and/or perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

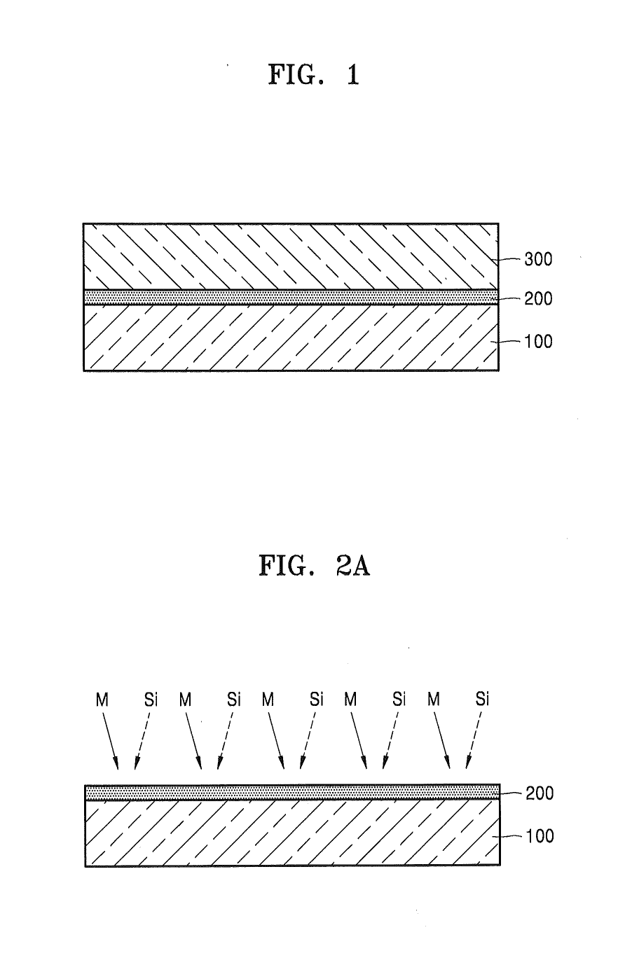

FIG. 1 is a schematic cross-sectional view of a semiconductor structure according to some embodiments of the present inventive concepts. Referring to FIG. 1, the semiconductor structure may include a silicon substrate 100, a buffer layer 200 formed on the silicon substrate 100, and at least one semiconductor layer 300 grown on the buffer layer 200.

The semiconductor layer 300 is formed on the silicon substrate 100 through the buffer layer 200. The semiconductor layer 300 may have a lattice constant that is 1.03 to 1.09 times greater than that of the silicon substrate 100. The semiconductor layer 300 may include a semiconductor material that includes a group IV material, for example, germanium (Ge) or a semiconductor material that includes a group III-V material, for example, at least one of gallium arsenide (GaAs), aluminum arsenide (AlAs), indium gallium arsenide (InGaAs), indium phosphide (InP), and indium aluminum arsenide (InAlAs).

When the semiconductor layer 300 includes Ge, GaAs, or AlAs as a semiconductor material, the lattice constant of the semiconductor layer 300 may be approximately 0.565 nm. If the lattice constant of the silicon substrate 100 is approximately 0.543 nm, the lattice constant of the semiconductor layer 300 may be approximately 1.04 times greater than that of the silicon substrate 100. That is, the lattice constant difference between the semiconductor layer 300 and the silicon substrate 100 is approximately 4%.

When the semiconductor layer 300 includes one of InGaAs, InP, and InAlAs as a semiconductor material, the semiconductor layer 300 may have a lattice constant of approximately 0.58 nm. If the lattice constant of the silicon substrate 100 is approximately 0.543 nm, the lattice constant of the semiconductor layer 300 may be approximately 1.07 times greater than that of the silicon substrate 100. That is, the lattice constant difference between the semiconductor layer 300 and the silicon substrate 100 is approximately 7%.

If the semiconductor layer 300 described above is directly grown on the silicon substrate 100, threading dislocations may occur due to the lattice constant difference, which may lead to the reduction of not only the performance of the semiconductor structure but also the physical properties of the semiconductor layer 300. In order to address this problem, the buffer layer 200 for lattice matching of the semiconductor layer 300 is disposed between the silicon substrate 100 and the semiconductor layer 300.

When the semiconductor layer 300 includes at least one of Ge, GaAs, AlAs, InGaAs, InP, and InAlAs as a semiconductor material, it may be unnecessary to consider a problem of cracks in the semiconductor layer 300 that is caused in the process of fabricating the semiconductor layer 300 due to a thermal expansion coefficient difference between the semiconductor layer 300 and the silicon substrate 100. This is because when considering a point that the temperature of, for example, 700° C., for forming the semiconductor layer 300 described above is lower than the temperature of, for example, 1,000° C., for forming the semiconductor layer 300 that includes, for example, GaN, the number of cracks that are generated in the cooling process after growing the semiconductor layer 300 is relatively small compared to the semiconductor layer 300 that includes GaN.

The buffer layer 200 may include a metal silicide compound for the lattice matching with the semiconductor layer 300. Since the buffer layer 200 includes the metal silicide compound, the buffer layer 200 may have a lattice constant that is the same as or similar to that of the semiconductor layer 300. This is more effective when a lattice constant difference between the semiconductor layer 300 and the silicon substrate 100 is in a range from about 3% to about 9%, for example, when the semiconductor layer 300 includes at least one of, for example, Ge, GaAs, AlAs, InGaAs, InP, and InAlAs. In the case when the lattice constant difference between the semiconductor layer 300 and the silicon substrate 100 exceeds 9%, for example, when the semiconductor layer 300 includes GaN, it may exceed the lattice matching range that may be achieved by the inclusion of the metal silicide compound. Thus, the use of a semiconductor layer 300 having a lattice constant difference of between about 3% and about 9% with respect to the silicon substrate 100 may be critical to achieving results as described herein.

As an example of the buffer layer 200 that has a lattice constant that is the same as or similar to that of the semiconductor layer 300, the buffer layer 200 may have a lattice constant that is greater than that of the silicon substrate 100, but the same as or smaller than that of the semiconductor layer 300. For example, the buffer layer 200 may include a metal silicide compound that includes iron (Fe), for example, Fe₃Si. The lattice constant of Fe₃Si is approximately 0.565 nm, which may match up with the lattice constant of the semiconductor layer 300 that includes Ge, GaAs, or AlAs. In this way, at least a portion of the buffer layer 200 may have a lattice constant that matches up with that of the semiconductor layer 300. Here, the “matching up” of lattice constants, denotes that the lattice constants are equal to or within two decimal places in a nanometer (nm) unit. As another example, the buffer layer 200 may include a metal silicide compound that includes at least one selected from the group consisting of Ni, Pd, Mn, Mo, W, and Co.

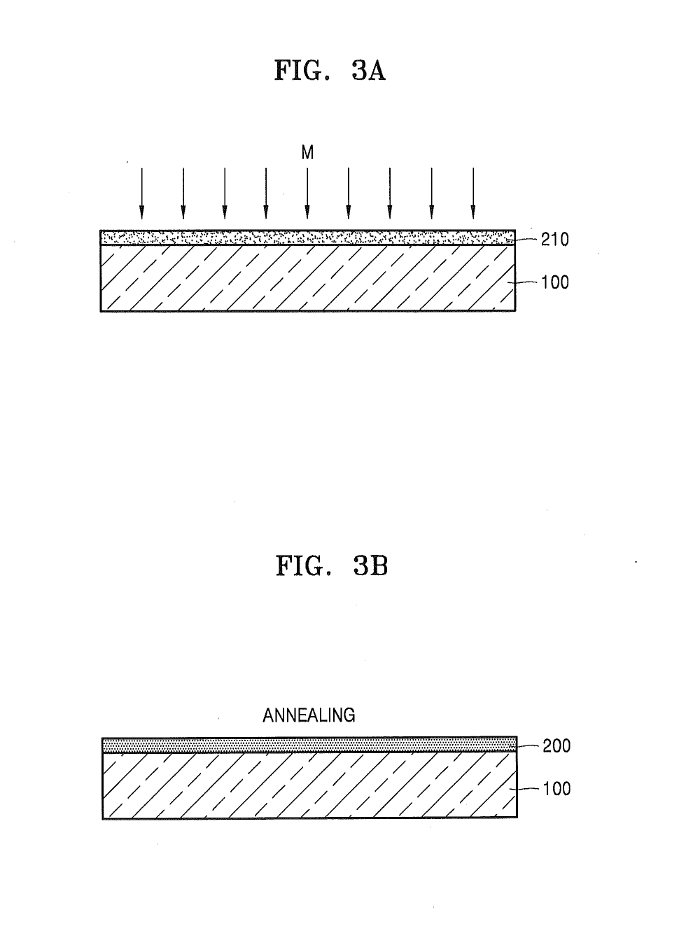

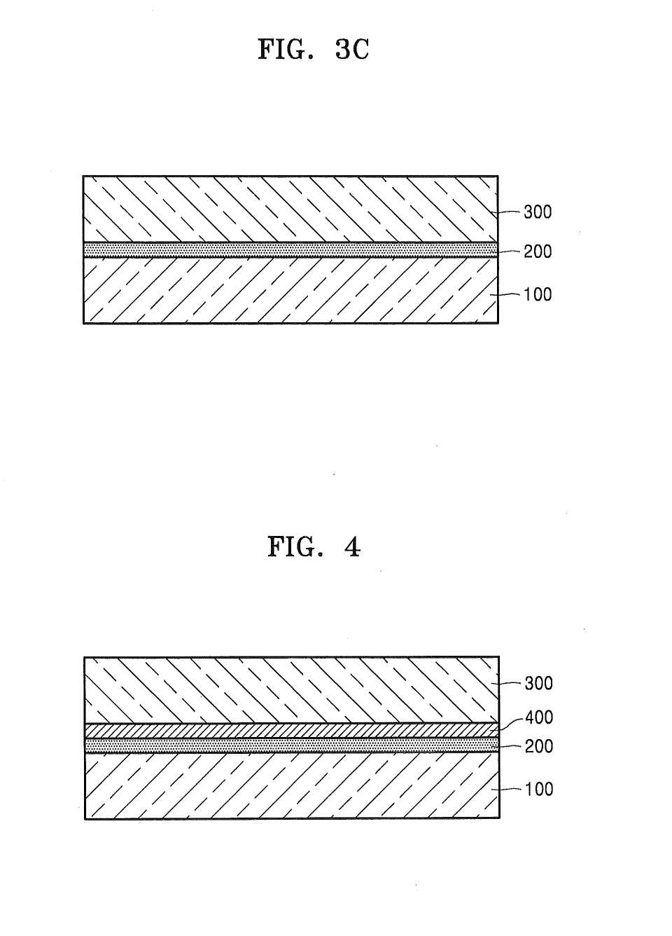

The buffer layer 200 may have a thickness in a range from about 1 nm to about 10 nm. When the thickness of the buffer layer 200 exceeds 10 nm, a portion of a metal layer 210 (refer to FIG. 3A) may not be transformed into a metal silicide compound in a process of forming the buffer layer 200, and thus, may result in the reduction of the performance of the semiconductor structure or the physical properties of the semiconductor layer 300. When the thickness of the buffer layer 200 is less than 1 nm, defects that occur at an interface between the buffer layer 200 and the silicon substrate 100 may reach the semiconductor layer 300. Thus, the thickness of the buffer layer 200 may also be critical to achieving results described herein.

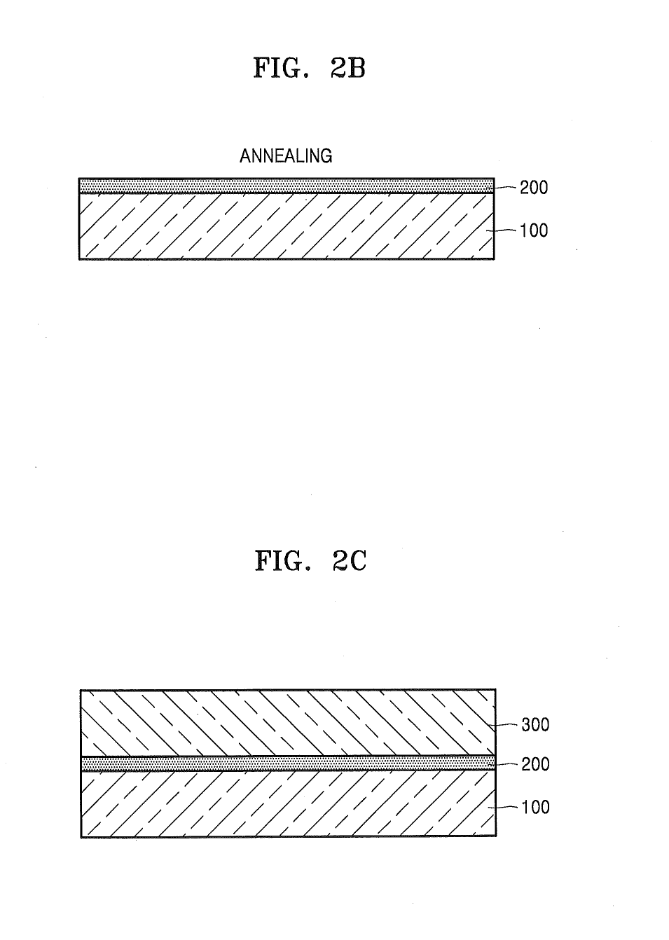

FIGS. 2A through 2C are schematic cross-sectional view showing a method of fabricating the semiconductor structure of FIG. 1, according to some embodiments of the present inventive concepts.

Referring to FIG. 2A, a metal material M and a silicon material Si are co-deposited on the silicon substrate 100 at a predetermined temperature. Through the co-deposition, the buffer layer 200 that includes a metal silicide compound is formed on the silicon substrate 100. The co-deposition method may include sputtering deposition or evaporation, but is not limited thereto. The predetermined temperature may be a temperature that is greater than room temperature. The metal material M may be at least one selected from the group consisting of Fe, Ni, Pd, Mn, Mo, W, and Co.

The physical properties of the metal silicide compound may vary according to deposition parameters, such as a deposition speed or a deposition temperature. For example, when Fe is supplied as the metal material M, ratios of the metal silicide compounds, such as FeSi, Fe₂Si, and Fe₃Si, may vary in the buffer layer 200 according to the deposition temperature. Accordingly, the lattice constant of the buffer layer 200 may vary. The buffer layer 200 may include Fe₃Si having a lattice constant of 0.565 nm, and thus, at least a portion of the buffer layer 200 may have a lattice constant that is the same as that of the semiconductor layer 300.

Referring to FIG. 2B, an annealing is performed on the buffer layer 200 formed on the silicon substrate 100. Through the annealing, the crystal structure of the buffer layer 200 may be transformed from an amorphous state to a crystalline state. The transformation may be more effective when the deposition speed is high. For example, when Fe as a metal material M and a silicon material are co-deposited respectively at a speed of 0.15 nm/sec and at a speed of 0.08 nm/sec on the silicon substrate 100, at least a portion of the buffer layer 200 may include an amorphous state metal silicide compound. The amorphous state metal silicide compound may be transformed to a crystalline state metal silicide compound by annealing at a temperature of, for example, 250° C. or 350° C. The annealing process may not necessarily be performed. For example, when a deposition is performed on the silicon substrate 100 at a low speed, for example, Fe is supplied at a speed of 0.027 nm/sec and Si is supplied at a speed of 0.014 nm/sec, a crystalline state metal silicide compound may be obtained without performing an annealing process.

Referring to FIG. 2C, the semiconductor layer 300 may be epitaxially grown on the buffer layer 200. As described above, at least a portion of the buffer layer 200 may have a lattice constant that is the same as that of the semiconductor layer 300. Accordingly, when the semiconductor layer 300 is epitaxially grown on the buffer layer 200, lattice mismatching may be reduced. The semiconductor layer 300 may be grown by various ways, for example, a reduced pressure chemical vapor deposition (RP-CVD) process, an ultra-high vacuum chemical vapor deposition (UHV-CVD) process, or a metal organic chemical vapor deposition (MO-CVD) process. However, the processes for forming the semiconductor layer 300 are not limited thereto, and other appropriate processes may be employed.

FIGS. 3A through 3C are schematic cross-sectional view showing a method of fabricating the semiconductor structure of FIG. 1, according to further embodiments of the present inventive concepts.

Referring to FIG. 3A, a metal layer 210 is formed by supplying a metal material M on the silicon substrate 100 at room temperature. An example of the metal material M may be at least one of Fe, Ni, Pd, Mn, Mo, W, or Co. The metal layer 210 may be formed by using, for example, an atomic layer deposition (ALD) method, a physical vapor deposition (PVD) method, or a chemical vapor deposition (CVD) method.

Referring to FIG. 3B, an annealing is performed on the metal layer 210 formed on the silicon substrate 100. While annealing, a metal silicide compound is formed by mixing the metal material M of the metal layer 210 and silicon of the silicon substrate 100. Through this process, the buffer layer 200 having the metal silicide compound may be formed on the silicon substrate 100. At least a portion of the buffer layer 200 may have a lattice constant that matches with that of the semiconductor layer 300. For example, in FIG. 3A, when Fe is supplied as the metal material M, the metal layer 210 that includes Fe may be transformed to the buffer layer 200 that includes a metal silicide compound, for example, Fe₃Si, due to the annealing. The lattice constant of Ge or GaAs is 0.565 nm and that of Fe₃Si is 0.565 nm. Therefore, the semiconductor layer 300 that includes Ge or GaAs may be lattice matched with the buffer layer 200 that includes the metal silicide compound. Physical properties of the metal silicide compound may be controlled according to a deposition temperature. For example, when the metal material M is Fe, the lower the deposition temperature, the higher the ratio of FeSi, and the higher the deposition temperature, the higher the ratio of Fe₃Si. For example, when the deposition temperature of the metal layer 210 is less than 200° C., the ratio of FeSi may be the largest in a metal silicide compound that includes Fe. When the deposition temperature is between 200° C. and 400° C., the ratio of Fe₂Si may be the largest, and when the deposition temperature exceeds 400° C., the ratio of Fe₃Si may be the largest. Here, the deposition temperature of the metal layer 210 may be less than 800° C.

Referring to FIG. 3C, the semiconductor layer 300 may be epitaxially grown on the buffer layer 200. As described above, at least a portion of the buffer layer 200 may have a lattice constant that is the same as that of the semiconductor layer 300. Accordingly, when the semiconductor layer 300 is epitaxially grown on the buffer layer 200, defects due to lattice mismatching may be reduced. The semiconductor layer 300 may be grown in various ways, for example, an RP-CVD process, a UHV-CVD process, or a MO-CVD process. However, the processes for forming the semiconductor layer 300 are not limited thereto, and other processes may be employed.

FIG. 4 is a schematic cross-sectional view of a semiconductor structure according to still further embodiments of the present inventive concepts. Referring to FIG. 4, the semiconductor structure includes a silicon substrate 100, a buffer layer 200 formed on the silicon substrate 100, a seed layer 400 formed on the buffer layer 200, and a semiconductor layer 300 formed on the seed layer 400. Like reference numerals are used to indicate elements that are substantially identical to the elements of FIG. 1, and thus the detailed description thereof is not repeated.

In the embodiment of FIG. 4, the seed layer 400 for growing the semiconductor layer 300 is disposed between the buffer layer 200 and the semiconductor layer 300. Since the seed layer 400 is disposed between the buffer layer 200 and the semiconductor layer 300, the penetration of threading dislocations from the buffer layer 200 into the semiconductor layer 300 may be stably blocked or reduced.

The seed layer 400 is formed on the buffer layer 200 before forming the semiconductor layer 300 at a temperature lower than that of the formation of the semiconductor layer 300. For example, when the temperature for forming the semiconductor layer 300 is in a range from about 400° C. to about 700° C., the temperature for forming the seed layer 400 may be in a range from about 300° C. to about 500° C. The seed layer 400 may be formed by various ways, for example, an RP-CVD process, a UHV-CVD process, or a MO-CVD process. However, the processes for forming the seed layer 400 are not limited thereto, and other processes may be employed.

The seed layer 400 may have a lattice constant matching with that of the semiconductor layer 300. Since the lattice constant of the seed layer 400 is matched with that of the semiconductor layer 300, the crystal quality of the semiconductor layer 300 grown on the seed layer 400 may be improved. The seed layer 400 may have a thickness in a range from about 5 nm to about 10 nm.

As an example of the seed layer 400 that has the same lattice constant as that of the semiconductor layer 300, the seed layer 400 may include at least one of Ge, GaAs, AlAs, InGaAs, InP, and InAlAs. The seed layer 400 may be formed of the same as or different material from the semiconductor layer 300. For example, the seed layer 400 and the semiconductor layer 300 both may include Ge or GaAs so that the seed layer 400 and the semiconductor layer 300 have the same material. Also, the seed layer 400 and the semiconductor layer 300 may respectively include Ge and GaAs or GaAs and Ge so that the seed layer 400 and the semiconductor layer 300 have different materials.

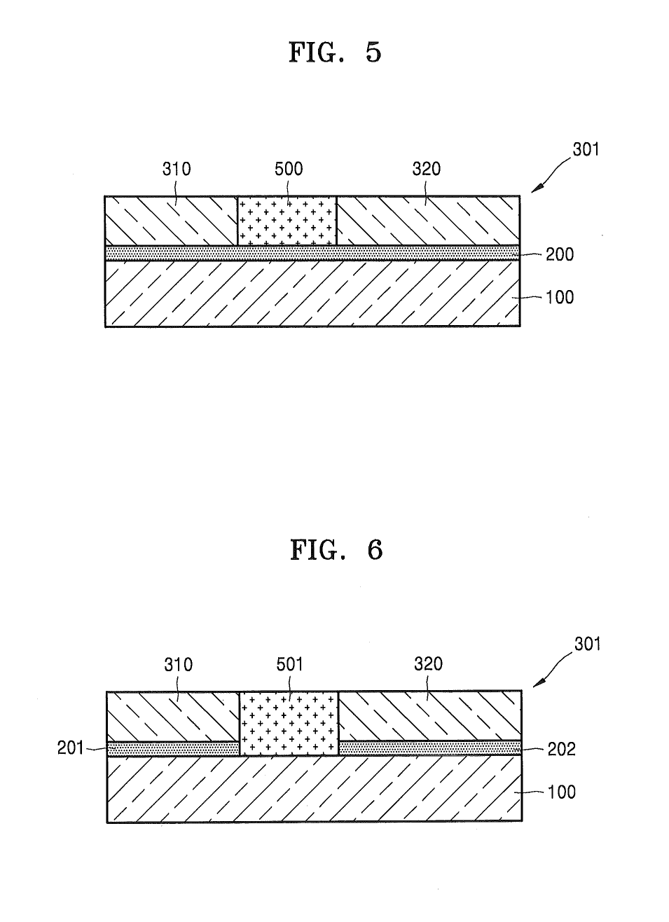

FIG. 5 is a schematic cross-sectional view of a semiconductor structure according to yet further embodiments of the present inventive concepts. Referring to FIG. 5, the semiconductor structure includes a silicon substrate 100, a buffer layer 200 formed on the silicon substrate 100, a semiconductor layer 301 formed on the buffer layer 200, and spacer 500. Like reference numerals are used to indicate elements that are substantially identical to the elements of FIG. 1, and thus the detailed description thereof is not repeated.

The semiconductor layer 301 includes a first semiconductor layer 310 and a second semiconductor layer 320 that are separated from each other on the buffer layer 200. The first semiconductor layer 310 and the second semiconductor layer 320 may include different semiconductor materials. For example, the first semiconductor layer 310 may include a group IV material, for example, Ge, and the second semiconductor layer 320 may include a group III-V material, for example, at least one of GaAs, AlAs, InGaAs, InP, and InAlAs. The first semiconductor layer 310 and the second semiconductor layer 320 may be sequentially or simultaneously formed on the buffer layer 200.

The spacer 500 is disposed between the first semiconductor layer 310 and the second semiconductor layer 320 to block electrical contact between the first semiconductor layer 310 and the second semiconductor layer 320. The first semiconductor layer 310 contacts a side of the spacer 500 and the second semiconductor layer 320 contacts the other side of the spacer 500. The spacer 500 may include an insulating material, for example, silicon oxide (SiO₂).

As depicted in FIG. 5, the spacer 500 may be formed on a portion of the buffer layer 200. However, the spacer 500 may not be necessarily formed on the buffer layer 200. As depicted in FIG. 6, the spacer 500 may be formed on a portion of the silicon substrate 100. In this case, the buffer layer 200 may include a first buffer layer 201 and a second buffer layer 202 that are separated from each other. At least a portion of the first buffer layer 201 may have a lattice constant matching with that of the first semiconductor layer 310. At least a portion of the second buffer layer 202 may also have a lattice constant matching with that of the second semiconductor layer 320.

As described above, when the first second semiconductor layers 310 and 320 having different materials from each other are simultaneously formed on a single silicon substrate 100, a high performance complementary metal-oxide semiconductor (CMOS) may be realized.

While semiconductor structures and methods according to embodiments of the present inventive concepts have been described with reference to the figures. It should be understood that the exemplary embodiments described therein should be considered in a descriptive sense only and not for purposes of limitation. For example, in the embodiments described above, as an example, silicon has a lattice constant of 0.543 nm is described. However, the current invention is not limited thereto, and the lattice constant of silicon may vary according to the orientation thereof. Also, the embodiments of the present inventive concepts are not limited to the examples described above. It will be understood by those of ordinary skill in the art that various changes in form and details may be made therein without departing from the spirit and scope of the present inventive concepts as defined by the following claims.

What is claimed is:

1. A semiconductor structure comprising:
a silicon substrate;
at least one semiconductor layer that is formed on the silicon substrate and has a lattice constant in a range from about 1.03 to about 1.09 times greater than that of the silicon substrate; and
a buffer layer that is disposed between the silicon substrate and the semiconductor layer and comprises a metal silicide compound providing lattice matching with the semiconductor layer.

2. The semiconductor structure of claim 1, wherein the semiconductor layer comprises at least one of Ge, GaAs, AlAs, InGaAs, InP, and InAlAs as a semiconductor material.

3. The semiconductor structure of claim 1, wherein at least a portion of the buffer layer has a lattice constant matching with that of the semiconductor layer.

4. The semiconductor structure of claim 1, wherein the buffer layer has a lattice constant that is less than or equal to that of the semiconductor layer and greater than that of the silicon substrate.

5. The semiconductor structure of claim 3, wherein the buffer layer comprises a metal silicide compound that comprises at least one of Fe, Ni, Pd, Mn, Mo, W, and Co.

6. The semiconductor structure of claim 1, wherein the buffer layer has a thickness in a range from about 1 nm to about 10 nm.

7. The semiconductor structure of claim 1, further comprising a seed layer that is disposed between the buffer layer and the semiconductor layer and comprises a semiconductor layer material having a lattice constant matching with that of the semiconductor layer.

8. The semiconductor structure of claim 7, wherein a semiconductor material of the seed layer comprises at least one of Ge, GaAs, AlAs, InGaAs, InP, and InAlAs.

9. The semiconductor structure of claim 7, wherein the seed layer has a thickness in a range from about 5 nm to about 10 nm.

10. The semiconductor structure of claim 1, wherein the semiconductor layer comprises a first semiconductor layer and a second semiconductor layer that are separated from each other on the buffer layer, wherein the first semiconductor layer comprises Ge and the second semiconductor layer comprise at least one of GaAs, AlAs, InGaAs, InP, and InAlAs.

11. The semiconductor structure of claim 10, further comprising a spacer disposed between the first semiconductor layer and the second semiconductor layer.

12. The semiconductor structure of claim 11, wherein the spacer is disposed on the silicon substrate or the buffer layer.

13. The semiconductor structure of claim 11, wherein the buffer layer comprises a first buffer layer and a second buffer layer,
wherein at least portion of the first buffer layer has a lattice constant matching with that of the first semiconductor layer; and
wherein at least portion of the second buffer layer has a lattice constant matching with that of the second semiconductor layer.

14. A semiconductor structure, comprising:
a silicon substrate;
a metal silicide buffer layer on the silicon substrate, the metal silicide buffer layer having a lattice constant greater than that of the silicon substrate; and
an epitaxial semiconductor layer on the metal silicide buffer layer opposite the silicon substrate, the epitaxial semiconductor layer having a lattice constant greater than or equal to that of the buffer layer and within about 9 percent of that of the silicon substrate.

15. The semiconductor structure of claim 14, wherein the lattice constant of the epitaxial semiconductor layer is 3 percent to 9 percent greater than that of the silicon substrate.

16. The semiconductor structure of claim 15, wherein the epitaxial semiconductor layer comprises germanium (Ge), gallium arsenide (GaAs), aluminum arsenide (AlAs), indium gallium arsenide (InGaAs), indium phosphide (InP), and/or indium aluminum arsenide (InAlAs), and wherein the semiconductor layer is formed at a lower temperature than and comprises fewer cracks than a gallium nitride (GaN) layer.

17. The semiconductor structure of claim 15, wherein the epitaxial semiconductor layer is substantially free of threading dislocations.

18. The semiconductor structure of claim 17, further comprising:
a seed layer having a thickness of about 5 nanometers (nm) to about 10 nm, wherein the seed layer is between the metal silicide buffer layer and the epitaxial semiconductor layer, wherein a lattice constant of the seed layer matches the lattice constant of the epitaxial semiconductor layer.

19. The semiconductor structure of claim 15, wherein the epitaxial semiconductor layer defines a CMOS structure comprising different first and second epitaxial semiconductor layers that are laterally separated along a surface of the metal silicide buffer layer.

20. The semiconductor structure of claim 19, wherein the metal silicide buffer layer comprises first and second buffer layers laterally separated on a surface of the silicon substrate by an insulating spacer therebetween.
